(19) United States
(12) Patent Application Publication
(10) Pub. No.: US 2015/0376786 A1
(43) Pub. Date: Dec. 31, 2015

(54) Apparatus And Methods For Carousel Atomic Layer Deposition

(71) Applicants: Joseph YUDOVSKY, (US); Kaushal GANGAKHEDKAR, (US); Kevin GRIFFIN, (US)

(72) Inventors: Joseph Yudovsky, Campbell, CA (US); Kaushal GANGAKHEDKAR, San Jose, CA (US); Kevin Griffin, Livermore, CA (US)

(21) Appl. No.: 14/768,908

(22) PCT Filed: Feb. 20, 2014
(86) PCT No.: PCT/US14/17394

§ 371 Date: Aug. 19, 2015

Related U.S. Application Data
(60) Provisional application No. 61/766,975, filed on Feb. 20, 2013.

(51) Int. Cl. C23C 16/455; C23C 16/458

(52) U.S. Cl. CPC C23C 16/45544; C23C 16/45565; C23C 16/4584

(57) ABSTRACT

Gas distribution assemblies and susceptor assemblies made up of a plurality of pie-shaped segments which can be individually leveled, moved or changed. Processing chambers comprising the gas distribution assemblies, the susceptor assemblies and sensors with feedback circuits to adjust the gap between the susceptor and gas distribution assembly are also described. Methods of using the gas distribution assemblies, susceptor assemblies and processing chambers are also described.

### BACKGROUND

Embodiments of the invention generally relate to apparatus and methods for atomic layer deposition. In particular, embodiments of the invention are directed to apparatus and methods for carousel atomic layer deposition using showerhead assemblies and/or susceptor assemblies comprising a plurality of independently controllable pie-shaped segments.

Currently, linear spatial atomic layer deposition (ALD) single wafer reactors have a single piece graphite based susceptor to carry wafers. The design facilitates a reciprocating monolithic susceptor under a fixed showerhead for multi-layer angstrom level deposition. The wafer has to accelerate/decelerate every cycle which affects overhead time and throughput. Also, since a stationary injector has to cover the entire wafer area, the susceptor has to be three times longer than the wafer diameter. This increases the chamber and pumping volume nine times. Every time a wafer needs to be exchanged, the chamber needs to be re-stabilized for pressure, temperature and flow which takes a lot of overhead time. And hence the current linear chamber does not have large enough throughput.

The linear chambers have linear motors and mechanical rails inside vacuum and the components become more expensive and require longer leadtimes for vacuum compatibility. For better throughput, the susceptor has to reciprocate faster, making it necessary for wafers to be vacuum clamped to the susceptor. This increases the complexity of motion and system design.

Typically, the gap between the wafer and showerhead needs to be controlled to less than about 1 mm for optimal ALD performance. But because the susceptor is so long, the flatness of the susceptor cannot be tightly controlled and it expands unevenly because it is anchored at four points. The gap in current chamber designs is around 1.2 mm. There is no active gap control for controlling the gap between the wafer and the showerhead. Shims are used to control the gap which makes it a trial and error method. Also, the susceptor is supported at four places on the linear actuator, which makes integration difficult and expansion uneven.

Therefore, there is a need in the art for methods and apparatus capable of maintaining a tightly controlled gap during spatial atomic layer deposition.

### SUMMARY

Embodiments of the invention are directed to gas distribution assemblies comprising a plurality of pie-shaped segments. The plurality of pie-shaped segments are radially disposed about a central axis and include a plurality of radial channels. Each of the radial channels has a shape conforming to the shape of the pie-shaped segments.

In some embodiments, the at least one of the pie-shaped segments further comprises at least three leveling units. In one or more embodiments, each of the three leveling units is independently one of a kinematic mount and a voice coil.

Some embodiments further comprise a movable leading pie-shaped segment. In one or more embodiments, the movable leading pie-shaped segment is movable to allow a substrate to be placed under the gas distribution assembly.

In some embodiments, the plurality of pie-shaped segments and the movable leading pie-shaped segment combine to form a substantially round shape. In one or more embodiments, the movable leading pie-shaped segment is one or more of an active segment, a dummy segment, a heating segment and a plasma treatment segment. In some embodiments, the movable leading pie-shaped segment is a dummy segment that can be replaced with a pie-shaped segment with a different purpose.

In some embodiments, each of the plurality of pie-shaped segments is independently removable from the gas distribution assembly.

Additional embodiments of the invention are directed to susceptor assemblies comprising a rotatable center support and a plurality of pie-shaped segments. The plurality of pie-shaped segments are radially disposed about the rotatable center support. At least a portion of each pie-shaped segment contacts the rotatable center support.

In some embodiments, the rotatable center support comprises a quartz base and each of the plurality of pie-shaped segments is supported by the quartz base. In one or more embodiments, the quartz base comprises a solid disk which supports all of each of the plurality of pie-shaped segments. In some embodiments, the quart base comprises a plurality of spokes extending from a central axis forming a spoked frame and each of the pie-shaped segments rests on at least one spoke. In one or more embodiments, the quartz base comprises a plurality of gas passages in fluid communication with a plurality of apertures to allow a gas flowing through the gas passages to exit the passages and apply pressure to the pie-shaped segments.

In some embodiments, each of the pie-shaped segments is connected to the center support by at least two connection points. In one or more embodiments, each of the pie-shaped segments is quartz. In some embodiments, all of the pie-shaped segments are supported at an outer peripheral edge by a quartz gas bearing ring.

Some embodiments further comprise a lift to move the entire susceptor assembly in a vertical direction.

Further embodiments of the invention are directed to processing chamber comprising a gas distribution assembly, a susceptor assembly, a sensor, a plurality of gas bearing pads and a feedback circuit. The gas distribution assembly can be any of the described gas distribution assemblies. The susceptor assembly can be any of the described susceptor assemblies. The sensor is positioned to determine the distance between the gas distribution assembly and the susceptor assembly. The feedback circuit is connected the sensor and plurality of gas bearing pads the plurality of gas bearing pads to move all or a portion of the susceptor assembly closer to and further from the gas distribution assembly.

In some embodiments, the gas bearing pads are positioned above and below the susceptor assembly to move each of the pie-shaped segments independently. In one or more embodiments, the gas bearing pads are connected to independent lift actuators to move the gas bearing pads closer to and further from the gas distribution assembly. In some embodiments, the gas bearing pads are positioned at an outer peripheral edge of the susceptor assembly.

In some embodiments, the gas bearing pads are positioned toward the central axis of the susceptor assembly adjacent an inner edge of the pie-shaped segments. In one or more embodiments, the pie-shaped segments of the susceptor assembly are not supported at an outer peripheral edge. Some embodiments further comprise a heater adjacent the gas bearing pads to cause the pie-shaped segments to be independently tilted to raise or lower the outer peripheral edge of the pie-shaped segments relative to the inner edge.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows partial a top perspective view of a gas distribution assembly in accordance with one or more embodiments of the invention;

FIG. 2 shows a partial bottom perspective view of the gas distribution assembly of FIG. 1;

FIG. 3 shows a susceptor assembly in accordance with one or more embodiments of the invention;

FIG. 4 shows a susceptor assembly in accordance with one or more embodiments of the invention;

FIG. 5 shows a susceptor assembly in accordance with one or more embodiments of the invention;

FIG. 6 shows a partial view of a susceptor assembly in accordance with one or more embodiments of the invention;

FIG. 7 shows a partial view of a susceptor assembly in accordance with one or more embodiments of the invention;

FIG. 8 shows a cross-section of a processing chamber in accordance with one or more embodiments of the invention;

FIG. 9 shows a cross-section of a processing chamber in accordance with one or more embodiments of the invention;

FIG. 10 shows a cross-section of a processing chamber in accordance with one or more embodiments of the invention;

FIG. 11A shows a cross-section of a processing chamber in accordance with one or more embodiments of the invention;

FIG. 11B shows a cross-section of a processing chamber in accordance with one or more embodiments of the invention;

FIG. 12 shows a cross-section of a processing chamber in accordance with one or more embodiments of the invention; and

FIG. 13 shows a cross-section of a processing chamber in accordance with one or more embodiments of the invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the invention are directed to apparatus and methods to make a spatial ALD chamber which gives high throughput of wafers with continuous processing of multiple wafers on a susceptor and minimizes gap for best ALD performance and least precursor consumption. ‘Pie-style’ multi-piece showerhead and susceptor makes Carousel ALD chambers easily scalable to larger wafer sizes. As used in this specification and the appended claims, the term “pie-style” means a generally round shape which can be separated into multiple pieces.

Some embodiments of the invention are directed to multi-piece ‘pie-style’ showerhead injector design with radial channels for constant resident time. This makes the injector tightly controlled for flatness, and is easy to integrate, scalable and serviceable.

One or more embodiment have active individual Injector pies which can be mechanically leveled on three points with kinematic mounts and fixed on a datum structure to form a datum plane. The injector pies can either have purge holes for gas bearing to float on top of susceptor or have gas bearing pads mounted on it.

In some embodiments, each of injector pies have mechanical, pneumatic or electric mechanisms for leveling at three points. For example, mechanical with kinematic mounts, pneumatic with gas bearing and electrical with voice coil actuators at three points of each injector.

In some embodiments, one injector pie can be made inactive or dummy and be lifted for wafer transfer allowing the susceptor to be stationary in vertical direction. This may help by saving time, increasing throughput, gives longer life of susceptor and reduces complexity of chamber design.

In one or more embodiments, a large circular single or multi-piece piece ‘pie style’ susceptor carries multiple wafers which are rotated by a vacuum compatible rotation motor integrated with a small lift actuator for gap control.

In some embodiments, a multi-piece susceptor has ‘pie style’ susceptor pieces on quartz plate or spokes or rings. This makes the susceptor easily controlled for flatness and manufacturing. Quartz has multiple purposes, as a support base for susceptor pies, as window for heater coils/lamps to maintain efficiency and as gas bearing for floating susceptor pies.

In some embodiments, there are sensors on top of showerhead to provide active gap control for optimal process parameters. In one or more embodiments, gas bearings support and float susceptor and showerhead injectors, giving it better control of flatness for best gap control with showerhead injectors.

In some embodiments, a single or multi-piece susceptor is supported on outer diameter with a ceramic ring on three gas bearing pads supported on independent lift actuators for gap control. Three actuators give active control on leveling the plane of susceptor against the showerhead injectors plane. Integrated rotation motor(s) and lift(s) sync with the three bearing pad actuators for maintaining planarity.

In one or more embodiments, three gas bearing pads support and float single piece susceptor near the inner diameter. The susceptor is rotated and lifted with an integrated rotation motor and lift actuator for gap control. The rotation motor and lift can be mounted on top of showerhead or bottom of chamber.

In some embodiments, an entire top surface of a quartz window has gas bearing capability for floating single or multi-piece susceptor driven from center with a quartz torque shaft coupled to rotation motor. The quartz window will be made out of two plates, bottom plate will have milled channels for gas, and top plate if machined flat to cover the grooves. The two plates can be glued with high temperature glue or can be fused together. The quartz gas bearing table may not rotate, but can be lift actuated for gap control with injector pies.

In one or more embodiments, the quartz gas bearing is only on the outer diameter of the susceptor. So, the outer edge of susceptor floats on gas bearing ring, while the center of single piece or multi-piece susceptor pies are mechanically leveled and anchored on torque shaft that drive all pieces of the susceptor. This gives a low rotation mass and requires a small torque motor. The showerhead pies may need to be floated on top of the susceptor only on outer diameter and inner diameter surfaces.

In some embodiments, lift actuator(s) may be mounted on top of showerhead or on bottom of chamber. Top mounted actuation may have the benefit of better gap management because datum can be transferred from top of showerhead, than bottom mounted which may not have a direct reference to showerhead plane.

In one or more embodiments, transfer of the wafer can be done by several methods. In one method, all the showerhead pies (including dummy) are stationary but the entire susceptor assembly is lifted up and down for wafer transfer and for gap control. This means that every time a wafer transfer is done, the gap is checked again and corrected with feedback from laser sensors. In another method, a dummy showerhead pie is lifted up for wafer transfer and then brought down to same plane as stationary showerhead pies. However the susceptor assembly is stationary in the Z-direction during both process and transfer. This allows the gap to be maintained throughout the process and transfer steps.

In some embodiments, dummy showerhead space can be dual purposed for cleaning of wafers and plasma.

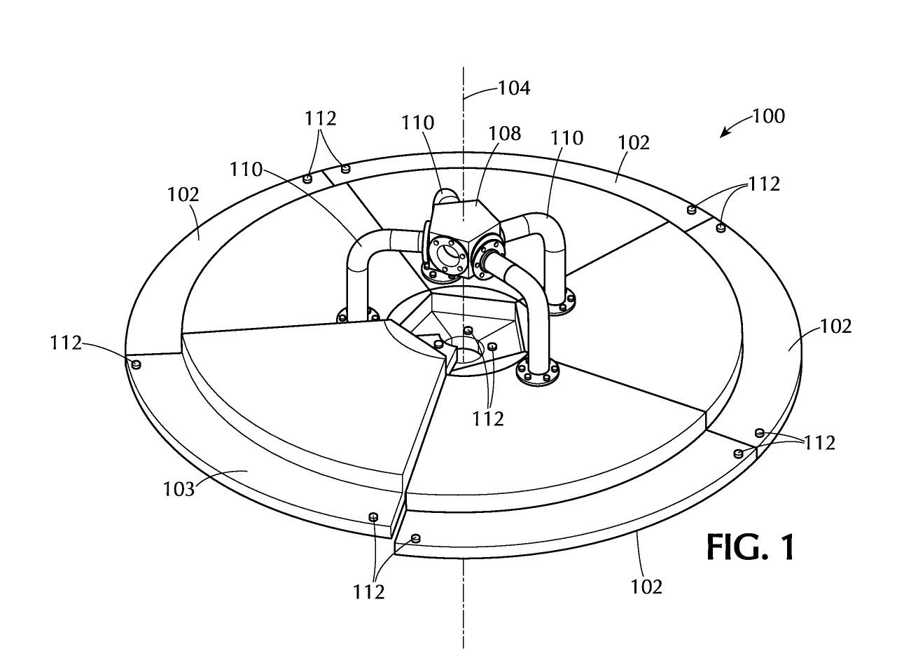

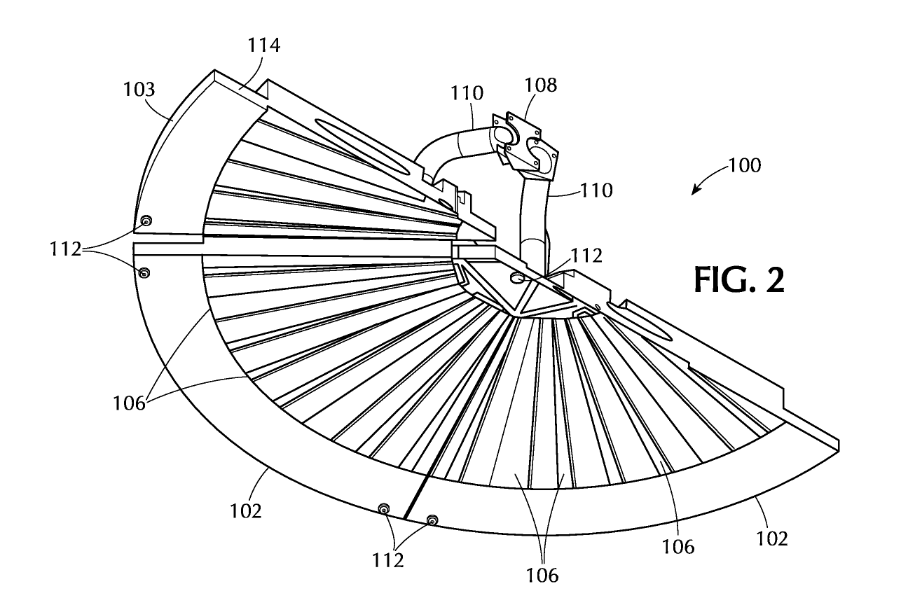

Accordingly, FIG. 1 shows a top view of a gas distribution assembly 100 in accordance with one or more embodiments of the invention. FIG. 2 shows the bottom view of a portion of the gas distribution assembly 100 of FIG. 1. The terms “gas distribution assembly”, “showerhead”, “showerhead assembly” and the like are used interchangeably.

With reference to FIGS. 1 and 2, the gas distribution assembly comprises a plurality of pie-shaped segments 102 which are radially disposed about a central axis 104. As shown in FIG. 1, the central axis 104 may be an imaginary point or axis about which the plurality of pie-shaped segments 102 are arranged. In some embodiments, the segments are separate components which can be assembled to form a complete, generally circular, gas distribution assembly and is not a single component divided into segments by gas channels or some other imaginary or hypothetical boundary.

The active pie-shaped segments 102 include a plurality of radial channels 106. Each of the radial channels 106 shown have a shape that conforms to the shape of the pie-shaped segments 102. Meaning, that the shape of the radial channels 106 is such that each point of a wafer passing beneath the radial channel 106 would have about an equal residence time beneath the channel. For example, the inner edge of a wafer rotating about the central axis 104 beneath the pie-shaped segments 102 would be traveling at a different linear velocity than the outer edge of the same wafer. The radial channels 106 have a larger width at the outer edge than the inner edge so the amount of time spent under the channel would be about the same for the inner edge and outer edge of the wafer in spite of this difference in linear velocities. Stated differently, the radial channels 106 may have a pie-shape similar in relative dimensions to the shape of the pie-shaped segment 102. The actual dimensions of each channel can differ from the adjacent channels, as shown in FIG. 2. This may allow for greater exposure time to some gases versus other gases.

As used in this specification and the appended claims, an “active” pie-shaped segment 102 is one in which wafer processing can be accomplished. An active pie-shaped segment 102 can include radial channels 106 or a showerhead-type configuration, or any other processing configuration. A “dummy” segment is one in which there is no processing performed. For example, a solid pie-shaped segment can be used as a “dummy” segment. A “dummy” segment can be identical in structure to an active segment just without being used to process a wafer. Each of the pie-shaped segments, independently, can be an active segment or a dummy segment.

The gas distribution assembly 100 may include one or more gas manifold 108. The gas manifold 108 shown is connected to the individual pie-shaped segments 102 by a conduits 110. The gas manifold 108 can be in fluid communication with a processing gas source (e.g., a gas cylinder, house gas line, or precursor ampoule). The processing gas flows from the processing gas source into the gas manifold 108 where it is directed to the active pie-shaped segments 102. While a single gas manifold 108 is shown in the Figures, it will be understood that more than one gas manifold 108 can be incorporated with each manifold being connected to the active pie-shaped segments by conduits. Additionally, the single manifold 108 housing shown may be configured to distribution more than one gas simultaneously to the active pie-shaped segments 102. For example, the gas manifold 108 may be in fluid communication with a first reactive gas, a second reactive gas, a purge gas, and a vacuum source. Each of these gases and vacuum can be directed independently to one or more of the pie-shaped segments.

The gas distribution assembly 100 of some embodiments, has at least one pie-shaped segment 102 in which the gas channels 106 are in an ABABA configuration. Meaning that the gas channels comprise, in order, a first reactive gas channel, a second reactive gas channel, a first reactive gas channel, a second reactive gas channel and a first reactive gas channel. A wafer passed across the surface of this segment, in either direction, will have two layers deposited thereon. Additional gas channels can be included between the A and B channels, including purge gas channels and vacuum channels to isolate the gas flows and minimize gas phase reactions of the precursors. In some embodiments, at least one of the pie-shaped segments 102 are arranged in an ABA configuration. The various segments 102 can be the same configurations, or different configurations allowing the deposition of a pure film or a mixed film as a wafer rotates through the entire carousel.

The embodiment shown in the Figures includes a movable leading pie-shaped segment 103. The movable leading pie-shaped segment 103 may be movable to allow a substrate (or wafer) to be placed under the gas distribution assembly 100. It can be seen from the Figures that the movable leading pie-shaped segment 103 is slightly higher than the remaining pie-shaped segments 102. The movable leading pie-shaped segment 103 can be the same as the other pie-shaped segments 102, an active segment or a dummy segment.

The movable leading pie-shaped segment 103 of some embodiments can be replaced with a different segment. For example, in one process, the movable leading pie-shaped segment 103 may initially be a dummy segment with no processing capability. After the first process, the movable leading pie-shaped segment 103 may be lifted to allow a wafer to be placed under the gas distribution assembly 100 and then replaced with an active pie-shaped segment. Accordingly, the movable leading pie-shaped segment can be any type of segment (e.g., active or dummy). In some embodiments, the movable leading pie-shaped segment 103 is one or more of an active segment, a dummy segment, a heating segment and a plasma treatment segment. The movable leading pie-shaped segment 103 in some embodiments is a dummy segment that can be replaced with a pie-shaped segment with a different purpose (e.g., active segment). In some embodiments, each of the plurality of pie-shaped segments 102, 103 is independently removable from the gas distribution assembly 100 and/or is independently replaceable. Any of the individual injector pies, or pie-shaped segments, can be made inactive or dummy and be lifted for wafer transfer allowing the susceptor to be stationary in the vertical direction.

In some embodiments, the overall shape of the gas distribution assembly 100, including the combination of all of the pie-shaped segments, forms a substantially round shape. As used in this specification and the appended claims, the term “substantially round” means that the overall shape of the gas distribution assembly is generally circular, it does not imply any specific degree of precision or accuracy.

Each of the individual pie-shaped segments 102 and the movable leading pie-shaped segment 103 can be leveled independent of the other pie-shaped segments 102, 103. In the embodiment shown in the Figures, at least one of the pie-shaped segments 102 includes at least three leveling units 112. By incorporating at least three leveling units 112, the individual pie-shaped segments 102, 103 can be leveled to be parallel to the plane of a susceptor or wafer without the need to level a single large gas distribution assembly 100. The number of leveling units 112 can vary. In some embodiments, there are three leveling units 112. This may be useful as three points are needed to define a plane. However, additional leveling units 112 can also be included. In some embodiments, one or more of the pie-shaped segments includes 4, 5, 6, 7, 8, 9, 10 or more leveling units 112.

The leveling units 112 can be distributed around the individual pie-shaped segments 102, 103. The pie-shaped segments 102, 103 shown in FIGS. 1 and 2 have a single leveling unit 112 at each of the corners of the roughly triangular shaped segment. This allows for the leveling of the inner edge and outer edge of the pie-shaped segments 102, 103 independently to allow the central portion to be fixed in height and the outer edge to be fixed in height and angled so that the front face 114 of the pie shaped segments 102, 103 are parallel to the relevant surface.

The leveling units 112 can be, independently, any suitable leveling unit. In some embodiments, the leveling units 112 comprise kinematic mounts. In some embodiments, the leveling units comprise voice coils. In one or more embodiments, each of the three leveling units 112 are independently one of a kinematic mount and a voice coil. The individual Injector pies which can be mechanically leveled on three points with kinematic mounts and fixed on a datum structure to form a datum plane. Each of the leveling units 112 can be independently a mechanical, pneumatic or electric mechanism for leveling the pie-shaped segments at three points. For example, mechanical with kinematic mounts, pneumatic with gas bearing and electrical with voice coil actuators at three points of each injector.

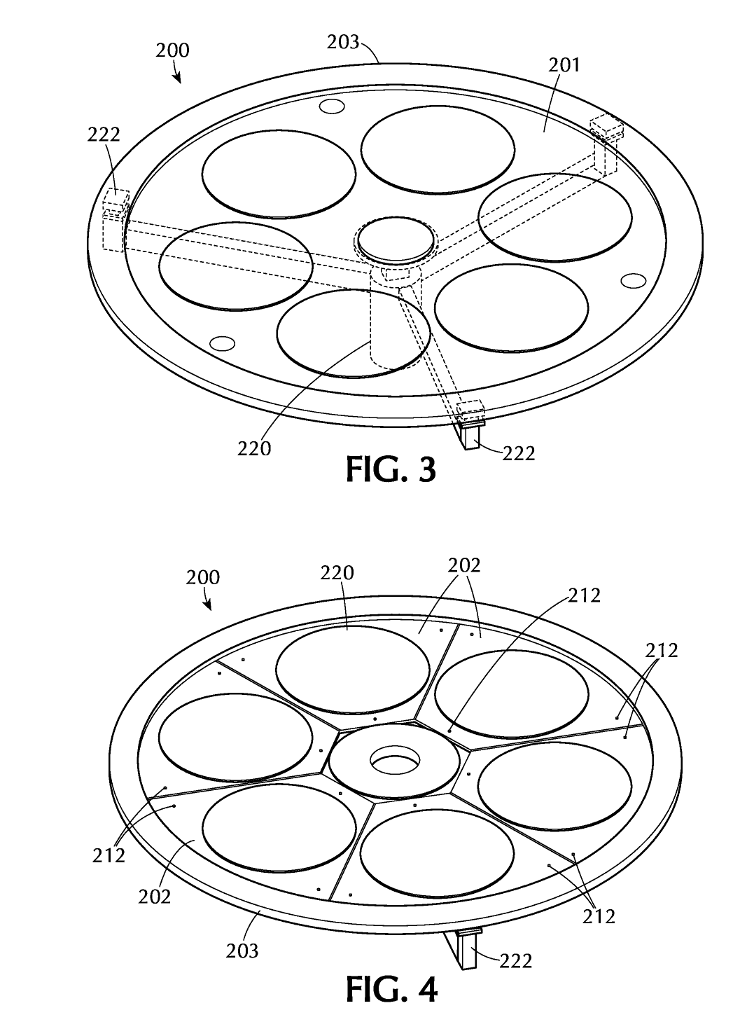

A susceptor assembly 200 is used to support one or more wafers during processing. FIG. 3 shows a single piece susceptor assembly 200 including a rotatable center support 220 and a plurality of spokes 222 extending from the center support 222 While three spokes 222 are shown, it will be understood that more or less spokes can be employed. The length and thickness of the spokes can vary depending on a number of factors including, but not limited to, the diameter of the susceptor 201 and the weight of the susceptor 201. The susceptor assembly 200 shown in FIG. 3 includes a base 203 which supports the susceptor 201. The base 203 is in turn supported by the plurality of spokes 222. The base 203 can be made of any suitable material including, but not limited to, quartz and ceramic.

The single piece susceptor shown in FIG. 3 may be particularly useful with the multi-piece gas distribution assembly 100 shown in FIGS. 1 and 2. Assuming that the susceptor 201 is sufficiently flat, the plurality of pie-shaped segments 102, 103 can be leveled so that each pie-shaped segment is parallel to the susceptor 201.

The susceptor 201 may include at least one recess (not shown) in the top surface of the susceptor 201. The recess can be sized to support a wafer by either complete contact with the back surface of the wafer, or by supporting an outer peripheral edge of the wafer. The recess of some embodiments is sized to ensure that the top surface of the wafer is substantially coplanar with the top surface of the susceptor 201.

FIG. 4 shows a susceptor assembly 200 with a plurality of pie-shaped segments 202 radially disposed about the rotatable center support 220. At least a portion of each pie-shaped segment 202 contacts the rotatable center support 220 so that the center support 220 can be used to rotate the entire susceptor assembly 200 including each individual pie-shaped segment 202. In some embodiments, the segments are separate components which can be assembled to form a complete, generally circular, susceptor assembly and is not a single component divided into segments by some imaginary or hypothetical boundary.

In the embodiment shown in FIG. 4, the rotatable center support 220 includes a single quartz base 203 comprising a solid disk of material. Each of the plurality of pie-shaped segments 202 are supported by the quartz base 203 and the quartz base is supported by a plurality of spokes 222 extending from the center support 220.

Each of the plurality of pie-shaped segments 202 includes a plurality of leveling units 212. This allows each of the pie-shaped segments 202 to be separately leveled relative to the gas distribution assembly so that during rotation of the susceptor assembly 200, the individual pie-shaped segments 202, and any wafer held thereon, remain a uniform distance from the gas distribution assembly.

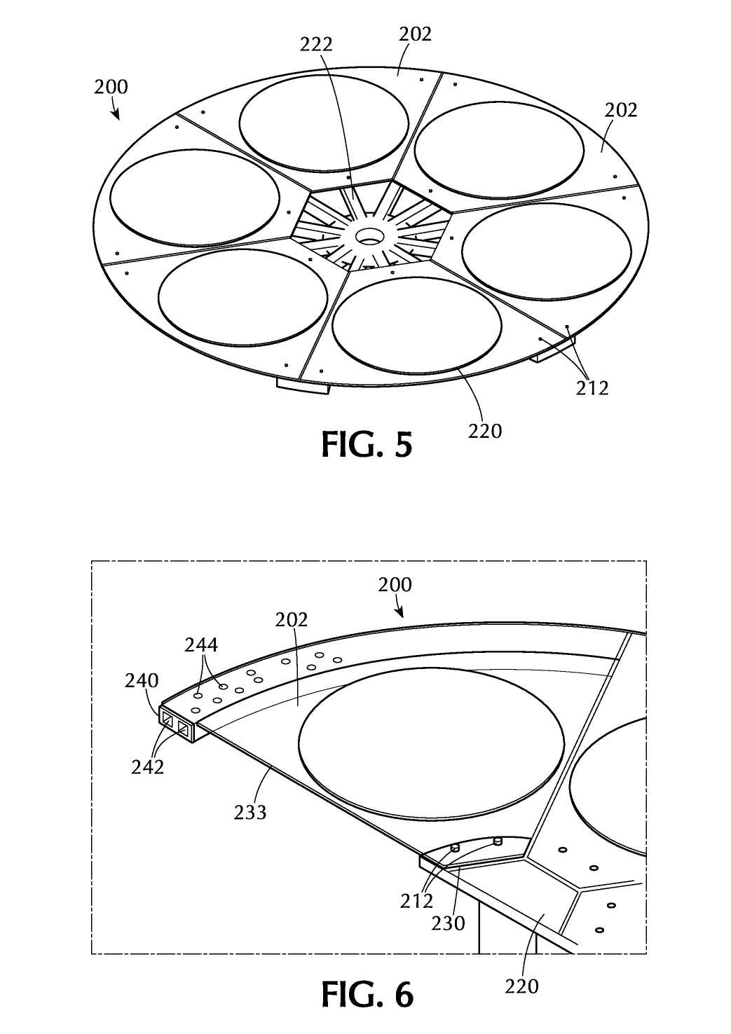

FIG. 5 shows another embodiment of the susceptor assembly 200 in which the base comprises a plurality of spokes 222 which extend from a central axis to form a spoked frame. Each of the pie-shaped segments 202 rest on the spokes 222 of the spoked frame so that edge of each segment 202 is supported directed over the spokes 222. This configuration decreases the overall weight of the base because the material required is wide enough to support the edges of the segments 202 without the need for additional material between the edges. The individual pie-shaped segments 202 include a plurality of leveling units 212, allowing each pie-shaped segment 202 to be independently leveled.

FIG. 6 shows another embodiment of a susceptor assembly 200 comprising a plurality of pie-shaped segments 202 connected to a central axis 220. The inner edge 230 of each pie-shaped segment 202 is connected to the central axis 220 with at least one leveling unit 212. The leveling units 212 provide an anchor point between the pie-shaped segments 202 and the central axis 220 and also allow the inner edge of each segment to be leveled. In some embodiments, the pie-shaped segments 202 are connected to the central axis 220 by at least two leveling units 212, as shown in the Figures. The outer edge 231 of each pie-shaped segment 202 is not physically connected to any component. Therefore, having at least two leveling units 212 on the inner edge 230 of each pie-shaped segment 202 helps prevent twisting of the individual segments 202 as a result of torque from the rotation of the central axis 220.

The outer edge 231 of each pie-shaped segment 202 rides on (or above) a gas bearing ring 240. The gas bearing ring 240 includes a plurality of gas passages 242 in fluid communication with a plurality of apertures 244 and a gas source (not shown). Gas flows from the gas source to the gas bearing ring 240, through the gas passages 242 and out of plurality of apertures 244 to apply pressure to the bottom side 233 of the pie-shaped segment 202 providing support for the outer edge 231 of the segment 202. The gas pressure flowing through the gas passages 242 and out the apertures 244 can be adjusted to cause the outer edge 231 of the segments 202 to move up or down, thus changing the tilt of the segments 202 and allowing the segments to be leveled.

The gas bearing ring 240 can be a single continuous piece or a plurality of separate segments. As a single piece, the flow of the gas through the gas bearing would be about the same throughout the entire ring. However, when multiple sections are used, the individual sections can allow for more precise control over the parallelism of the susceptor assembly relative to the gas distribution assembly.

The individual pie-shaped segments 202 can be made of any suitable material. Since most of the segment 202 is supported by a gas cushion and a connection at the central axis, it may be useful to use a light weight but strong material. In some embodiments, the individual pie-shaped segment 202 comprise quartz. By effectively making the susceptor assembly 200 of quartz, heating lamps, or optical devices, can be positioned below the susceptor to take advantage of the transparency of the quartz.

The gas bearing ring 240 can be made of any suitable material. In some embodiments, the gas bearing ring 240 comprises quartz. When the gas bearing ring 240 is quartz, heating lamps and other optical components can be positioned beneath the ring 240 without loss of effectiveness.

The size and position of the gas bearing ring 240 can be varied. The gas bearing ring 240 can extend from the edge of the central axis 220 to a point beyond the outer peripheral edge 231 of the susceptor pie-shaped segments 202. In some embodiments, the gas bearing ring 240 is positioned within 2 cm of the edge of the central axis 220.

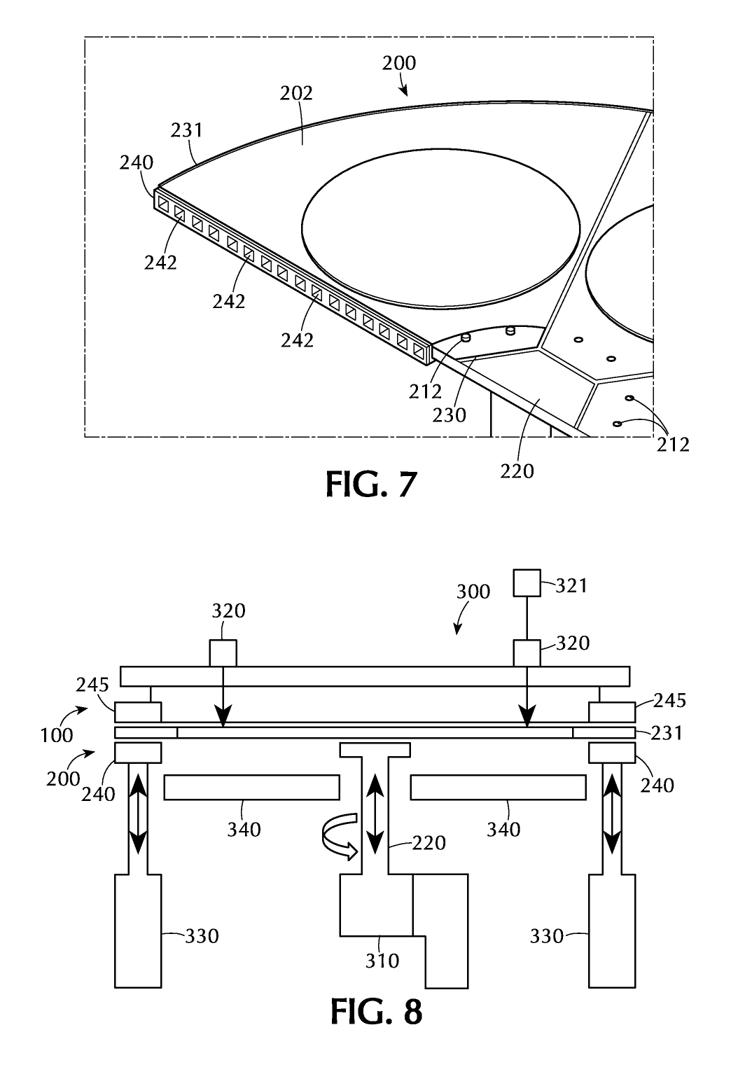

The gas bearing ring 240 can be of any suitable size an include any number of gas passages 242. FIG. 7 shows an alternate embodiment comprising a gas bearing ring 240. Here, the individual pie-shaped segments 202 are connected to the central axis 220 with at least one leveling unit 212 and the remaining portion of the segments are supported by a gas bearing ring 240. The gas bearing ring 240 in this embodiment is significantly larger than the gas bearing ring 240 in FIG. 6 and includes many more gas passages 242. The gas passages 242 serve the same purpose as that of FIG. 6, which is to provide support for and leveling of the pie-shaped segments 202.

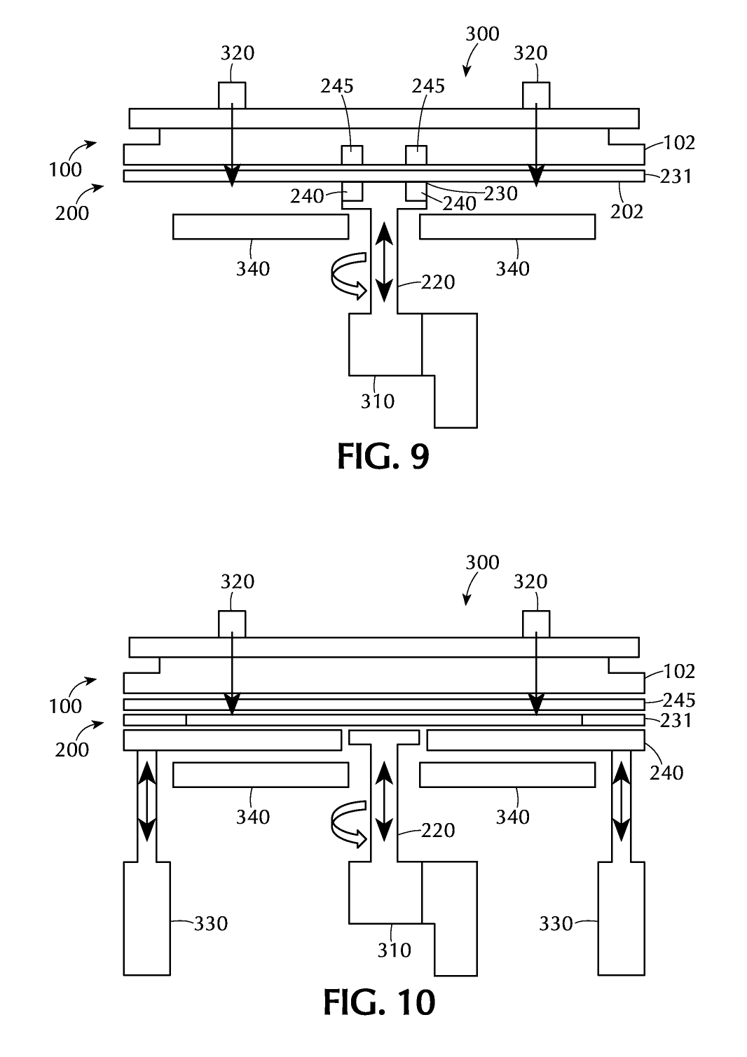

The gas bearing ring 240 can also be located immediately adjacent the central axis 220. FIG. 9 shows an embodiment of this sort. The gas bearing ring 240 immediately adjacent the central axis 220 of the susceptor assembly 200 causes the pie-shaped segments 202 to pivot, forcing the outer edge 231 up or down to make the pie-shaped segment 202 parallel to the gas distribution assembly 100.

Referring to FIG. 8, additional embodiments of the invention are directed to processing chambers 300 comprising a gas distribution assembly 100 and a susceptor assembly 200. The processing chamber 300 of some embodiments is a carousel type configuration in which multiple wafers are supported by the susceptor assembly 200 and rotated beneath the gas distribution assembly 100.

A sensor 320 is positioned to determine the distance between the gas distribution assembly 100 and the susceptor assembly 200. The sensor can be any suitable sensor including, but not limited to, laser sensors capable of measuring distances.

The distance between the gas distribution assembly 100 and the top surface of the wafer can be tuned and may have an impact on the efficiency of the gas flows from the gas distribution assembly. If the distance is too large, the gas flows could diffuse outward before encountering the surface of the wafer, resulting in a less efficient atomic layer deposition reaction. If the distance is too small, the gas flows may not be able to flow across the surface to the vacuum ports of the gas distribution assembly. In some embodiments, the gap between the surface of the wafer and the gas distribution assembly is in the range of about 0.5 mm to about 2.0 mm, or in the range of about 0.7 mm to about 1.5 mm, or in the range of about 0.9 mm to about 1.1 mm, or about 1.0 mm

The susceptor assembly 200 can be a single piece or multi-piece susceptor assembly as described above with respect to FIGS. 3 through 7. A gas bearing pad 240 is positioned below the susceptor assembly at the outer peripheral edge 231 of the susceptor assembly 200. A gas bearing pad 245 is also positioned above the susceptor assembly at the outer peripheral edge 231 of the assembly. The gas bearing pads 340, 345 can be used in conjunction to level the susceptor assembly.

A feedback circuit 321 is connected to the sensor 320 and a plurality of gas bearing pads 240, 245. The feedback circuit 321 communicates the distance measurements from the sensor 320 and provides instructions to the gas bearing pads 340, 345 to move all or a portion of the susceptor assembly 200 closer to and/or further from the gas distribution assembly 100.

As shown in FIG. 8, the susceptor assembly 200 may include a lift 310 to move the entire susceptor assembly 200 in a vertical direction. The lift 310 can be connected to the central axis 220 of the susceptor assembly 200. When positioning the susceptor assembly, the central axis 220 is lifted to the appropriate position and the outer peripheral edges of the susceptor are adjusted to make the susceptor parallel to the gas distribution assembly.

In some embodiments, the gas bearing pads 240 are connected to independent lift actuators 330 to move the gas bearing pads 240 closer to and further from the gas distribution assembly 100 and/or the susceptor assembly 200. Rather than, or in addition to, changing the pressure of the gas in the gas bearing pads 240, the lift actuators 330 can raise or lower the gas bearing pads 240 to affect the parallelism of the susceptor assembly relative to the gas distribution assembly.

A heater 340 or heating assembly may be positioned below the susceptor assembly 200 and/or adjacent the gas bearing pads 240. The heater can be positioned in any suitable location within the processing chamber including, but not limited to, below the susceptor assembly 200 and/or on the opposite side of the susceptor assembly 200 than the gas distribution assembly 100. The heater 340 provides sufficient heat to the processing chamber to elevate the temperature of the wafer to temperatures useful in the process. Suitable heating assemblies include, but are not limited to, resistive heaters and radiant heaters (e.g., a plurality of lamps) which direct radiant energy toward the bottom surface of the susceptor assembly.

The heater 340 can also be used to affect the parallelism of the susceptor assembly 200 relative to the gas distribution assembly 100. Elevating the temperature of a portion of the pie-shaped segments 202 of the susceptor assembly 200 can cause the assembly to pivot, raising or lowering the outer peripheral edge of the susceptor assembly. Additionally, the heater could be used to change the temperature of the gas exiting the gas bearing pads 240, 245, affecting the pressure of the gas impacting the susceptor assembly 200.

In the embodiment shown in FIG. 8, the gas bearing pads 240, 245 are positioned at the outer peripheral edge 231 of the susceptor assembly 200 and the pie-shaped segments 202. FIG. 9 shows an alternate embodiment of the processing chamber 300 in which the gas bearing pads 240, 245 are positioned toward the central axis 220 of the susceptor assembly 200 adjacent the inner edge 230 of the pie-shaped segments 202. In some embodiments, as shown in FIG. 9, the outer peripheral edge 231 of the pie-shaped segments 202 are not supported.

FIG. 10 shows another embodiment of the processing chamber 300 in which the gas bearing pad 240 below the susceptor assembly extends from about the point where the pie-shaped segments 202 are connected to the central axis 220 to the outer peripheral edge 231 of the segments 202. This is similar to the embodiment shown in FIG. 7. In addition, a gas bearing pad 245 is positioned between the susceptor assembly and the gas distribution assembly. This gas bearing pad can be a partial pad, meaning that there are gaps to allow the gases from the gas distribution assembly to pass therethrough to contact the wafers on the susceptor assembly. The upper gas bearing pad can also be substantially transparent, like quartz, to allow optical measurements and the passage of light therethrough.

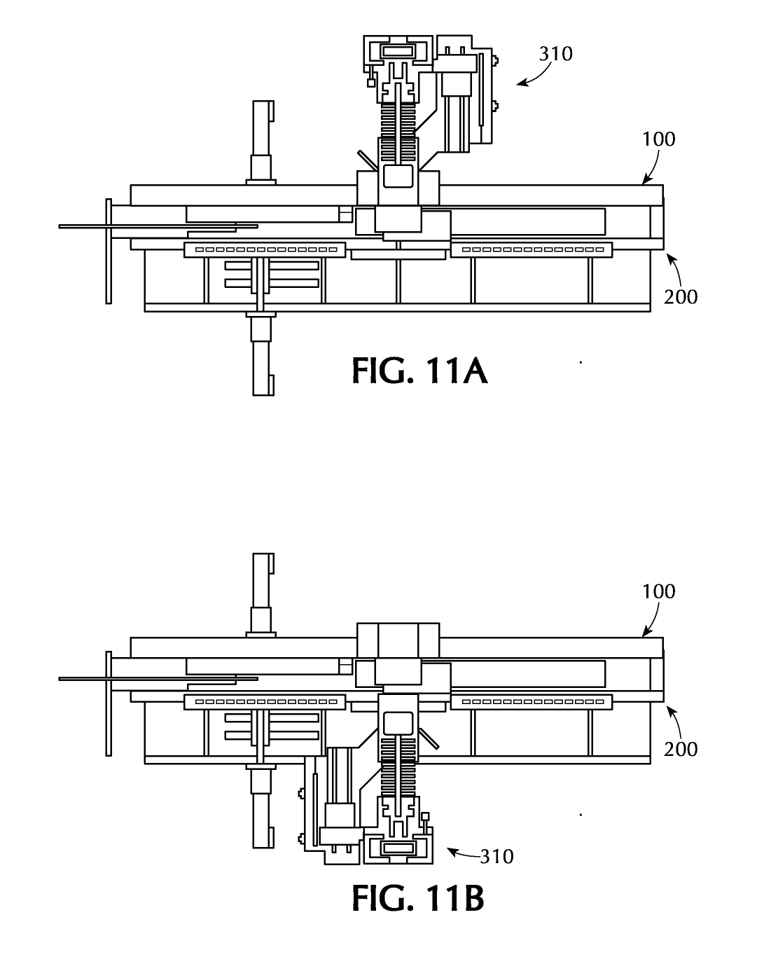

Referring to FIGS. 11A and 11B, the mechanism used to rotate the susceptor assembly 200 and/or raise/lower the susceptor assembly 200 can be positioned in a number of locations. FIG. 11A shows the rotator/actuator mechanism positioned above the susceptor assembly 200 and the gas distribution assembly 100. The mechanism can extend through the central region of the gas distribution assembly 100 to the susceptor assembly. In FIG. 11B, the rotator/actuator mechanism is positioned below the susceptor assembly 200.

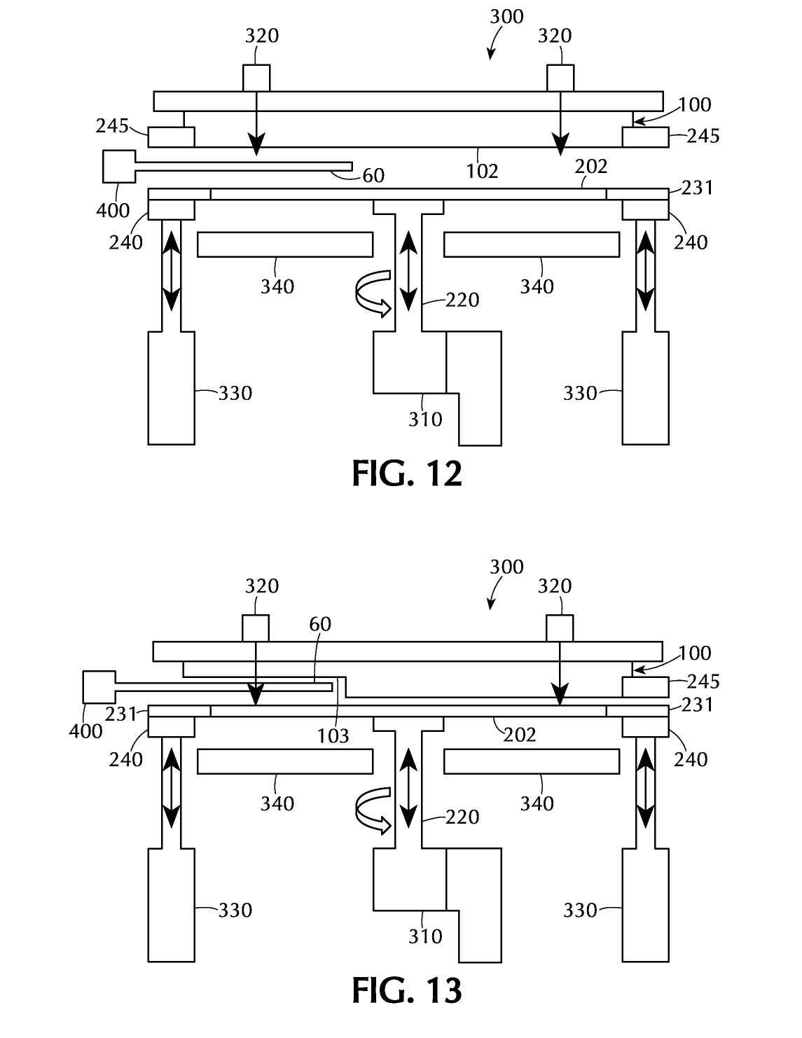

FIG. 12 shows a processing chamber 300 according to some embodiments in which a wafer is being loaded or unloaded. In this embodiment, the susceptor assembly 200 is moved down, away from the gas distribution assembly 100 to provide sufficient room for a robot art 400 to deliver a wafer 60, or pick up a wafer 60 from the susceptor assembly 200. When moving the susceptor assembly down, each of the actuators 330, the lift 310, the heaters 340 and the gas bearing pads 240 can be independently moved or moved in a group. Once the wafer 60 has been placed into a recess in one of the pie-shaped segments 202, the susceptor assembly can rotate to allow access to the next wafer, or can be moved toward the gas distribution assembly 100. Upon completion of the loading/unloading process, the susceptor assembly 200 is moved up toward the gas distribution assembly 100. In so doing, the lift 310, actuators 330, heaters 340 and gas bearing pads 240 are all raised, either independently or in groups. The parallelism of the susceptor segments is then adjusted using the gas bearing pads 240, or the other adjustment mechanisms described herein.

FIG. 13 shows another processing chamber 300 in which a wafer is being loaded or unloaded. Here, the susceptor assembly 200 and the gas distribution assembly 100 remain in substantially the same position and only the movable leading pie-shaped segment 103 is moved. FIG. 13 shows the movable segment 103 after it has been raised into a loading/unloading position. Once the wafer(s) has been loaded/unloaded, the movable segment 103 is lowered back into position and the parallelism is adjusted as described herein.

Substrates for use with the embodiments of the invention can be any suitable substrate. In detailed embodiments, the substrate is a rigid, discrete, generally planar substrate. As used in this specification and the appended claims, the term “discrete” when referring to a substrate means that the substrate has a fixed dimension. The substrate of specific embodiments is a semiconductor wafer, such as a 200 mm, 300 mm or 450 mm diameter silicon wafer.

As used in this specification and the appended claims, the terms “reactive gas”, “reactive precursor”, “first precursor”, “second precursor” and the like, refer to gases and gaseous species capable of reacting with a substrate surface or a layer on the substrate surface.

In some embodiments, one or more layers may be formed during a plasma enhanced atomic layer deposition (PEALD) process. In some processes, the use of plasma provides sufficient energy to promote a species into the excited state where surface reactions become favorable and likely. Introducing the plasma into the process can be continuous or pulsed. In some embodiments, sequential pulses of precursors (or reactive gases) and plasma are used to process a layer. In some embodiments, the reagents may be ionized either locally (i.e., within the processing area) or remotely (i.e., outside the processing area). In some embodiments, remote ionization can occur upstream of the deposition chamber such that ions or other energetic or light emitting species are not in direct contact with the depositing film. In some PEALD processes, the plasma is generated external from the processing chamber, such as by a remote plasma generator system. The plasma may be generated via any suitable plasma generation process or technique known to those skilled in the art. For example, plasma may be generated by one or more of a microwave (MW) frequency generator or a radio frequency (RF) generator. The frequency of the plasma may be tuned depending on the specific reactive species being used. Suitable frequencies include, but are not limited to, 2 MHz, 13.56 MHz, 40 MHz, 60 MHz and 100 MHz. Although plasmas may be used during the deposition processes disclosed herein, it should be noted that plasmas may not be required. Indeed, other embodiments relate to deposition processes under very mild conditions without plasma.

According to one or more embodiments, the substrate is subjected to processing prior to and/or after processing in the described chamber. This processing can be performed in the same chamber or in one or more separate processing chambers. In some embodiments, the substrate is moved from the first chamber to a separate, second chamber for further processing, with either or both chambers conforming to the described embodiments. The substrate can be moved directly from the first chamber to the separate processing chamber, or it can be moved from the first chamber to one or more transfer chambers, and then moved to the desired separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. The details of one such staged-vacuum substrate processing apparatus are disclosed in U.S. Pat. No. 5,186,718, entitled “Staged-Vacuum Wafer Processing Apparatus and Method,” Tepman et al., issued on Feb. 16, 1993. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants after forming the silicon layer on the surface of the substrate. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated about its own central axis throughout the entire process, or the substrate can be rotated by a small amount between exposure to different reactive or purge gases. Rotating the substrate during processing (either continuously or in steps) may help produce a more uniform deposition or etch by minimizing the effect of, for example, local variability in gas flow geometries.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

1-5. (canceled)

6. A susceptor assembly comprising:
a rotatable center support comprising a quartz base with a plurality of spokes extending from a central axis forming a spoked frame; and
a plurality of pie-shaped segments radially disposed about the rotatable center support, wherein at least a portion of each pie-shaped segment contacts the rotatable center support and each of the plurality of pie-shaped segments is supported by the quartz base and rests on at least one spoke.

7. (canceled)

8. The susceptor assembly of claim 6, wherein the quartz base comprises a solid disk which supports all of each of the plurality of pie-shaped segments.

9. (canceled)

10. The susceptor assembly of claim 6, wherein the quartz base comprises a plurality of gas passages in fluid communication with a plurality of apertures to allow a gas flowing through the gas passages to exit the passages and apply pressure to the pie-shaped segments.

11. The susceptor assembly of claim 6, wherein each of the pie-shaped segments is connected to the center support by at least two connection points.

12. The susceptor assembly of claim 6, wherein all of the pie-shaped segments are supported at an outer peripheral edge by a quartz gas bearing ring.

13. A processing chamber comprising:
a gas distribution assembly;
the susceptor assembly of claim 6;
a sensor positioned to determine a distance between the gas distribution assembly and the susceptor assembly;
a plurality of gas bearing pads; and
a feedback circuit connected the sensor and plurality of gas bearing pads the plurality of gas bearing pads to move all or a portion of the susceptor assembly closer to and further from the gas distribution assembly.

14. The processing chamber of claim 13, wherein the gas bearing pads are positioned above and below the susceptor assembly to move each of the pie-shaped segments independently.

15. The processing chamber of claim 13, wherein the gas bearing pads are positioned at one or more of an outer peripheral edge of the susceptor assembly or toward the central axis of the susceptor assembly adjacent an inner edge of the pie-shaped segments.

16. A susceptor assembly comprising:
a rotatable center support comprising a quartz base comprising a plurality of gas passages in fluid communication with a plurality of apertures; and
a plurality of pie-shaped segments radially disposed about the rotatable center support, wherein at least a portion of each pie-shaped segment contacts the rotatable center support and each of the plurality of pie-shaped segments is supported by the quartz base,
wherein the plurality of apertures allow a gas flowing through the gas passages to exit the passages and apply pressure to the pie-shaped segments.

17. The susceptor assembly of claim 16, wherein the quartz base comprises a solid disk which supports all of each of the plurality of pie-shaped segments.

18. The susceptor assembly of claim 16, wherein the quart base comprises a plurality of spokes extending from a central axis forming a spoked frame and each of the pie-shaped segments rests on at least one spoke.

19. The susceptor assembly of claim 16, wherein each of the pie-shaped segments is connected to the center support by at least two connection points.

20. The susceptor assembly of claim 16, wherein all of the pie-shaped segments are supported at an outer peripheral edge by a quartz gas bearing ring.

21. A processing chamber comprising:
a gas distribution assembly;
the susceptor assembly of claim 16;
a sensor positioned to determine a distance between the gas distribution assembly and the susceptor assembly;
a plurality of gas bearing pads; and
a feedback circuit connected the sensor and plurality of gas bearing pads the plurality of gas bearing pads to move all or a portion of the susceptor assembly closer to and further from the gas distribution assembly.

22. The processing chamber of claim 21, wherein the gas bearing pads are positioned above and below the susceptor assembly to move each of the pie-shaped segments independently.

23. The processing chamber of claim 21, wherein the gas bearing pads are positioned at one or more of an outer peripheral edge of the susceptor assembly or toward the central axis of the susceptor assembly adjacent an inner edge of the pie-shaped segment.
